(19) United States
(12) Patent Application Publication
(10) Pub. No.: US 2008/0215941 A1
(43) Pub. Date: Sep. 4, 2008

(54) Double-edge triggered scannable pulsed flip-flop for high frequency and/or low power applications

(75) Inventors: Christopher M. Durham, Round Rock, TX (US); Jenny Fan, Cedar Park, TX (US); Peter J. Klim, Austin, TX (US); Robert N. Krentler, Austin, TX (US)

Correspondence Address: CANTOR COLBURN LLP - IBM AUSTIN, 20 Church Street, 22nd Floor, Hartford, CT, 06103, US

(73) Assignee: International Business Machines Corporation, Armonk, NY (US)

(21) Appl. No.: 12/123,107

(22) Filed: May 19, 2008

Related U.S. Application Data
(63) Continuation-in-part of application No. 11/531,310, filed on Sep. 13, 2006.

(51) Int. Cl. G01R 31/28

(52) U.S. Cl. 714/726

(57) ABSTRACT

A design structure embodied in a machine readable medium used in a design process, includes a circuit for data storage. The circuit includes a double edge clock generation circuit for generating a pulse clock signal having first and second clock pulses for each clock cycle of a system clock; a scan clock generation circuit for generating first and second scan clock signals; a scannable pulse flip-flop circuit having a data input and a data output that are connected with an internal storage node, the scannable pulse flip-flop circuit including a scan input and a scan output connected with the internal storage node, and receptive to the pulse clock signal and the scan clock signals. The scannable pulse flip-flop circuit is configured to be operable in a function mode of operation and a scan mode of operation.

### CROSS-REFERENCE TO RELATED APPLICATIONS

This non-provisional U.S. patent application is a Continuation-In-Part of pending U.S. patent application Ser. No. 11/531,310, which was filed Sep. 13, 2006, and is assigned to the present assignee.

### BACKGROUND OF THE INVENTION

This invention relates to a memory storage element utilized in a digital circuit, and particularly to a design structure for a double edge-triggered scannable pulsed flip-flop that can be utilized in high frequency and/or low power digital circuits.

Microprocessors, microcontrollers, and Application-Specific Integrated Circuits (ASICs), as well as other digital components face an increasing demand for both high frequency clocking rates and low power dissipation. The demand for high frequency clocking rates derives from the need for data operations to occur at a high data-throughput rate. Meanwhile, the drive for new desk, counter, console, and rack applications demands power efficiency and miniaturization.

The total power consumption in a digital system is composed of several components and can be represented by the following equation:

P_{machine}=P_{clock}+P_{registers}+P_{logic}+P_{leakage}+P_{misc}

where:
P_{machine}=power dissipated by the entire machine (chip)
P_{clock}=power dissipated in the clock distribution system: proportional to frequency
P_{registers}=power dissipated by the pipeline registers: proportional to pipeline depth
P_{logic}=power dissipated by the logic circuitry: proportional to micro architecture
P_{leakage}=power dissipated by device leakage: proportional to chip device count
P_{misc}=power dissipated by input-output circuitry, PLL, array redundancy, etc.

In many digital components a high data-throughput rate is achieved using a pipelined datapath and pipeline registers. The pipeline registers require a clock signal to synchronize the data operations, which is distributed to all registers through a centralized distribution system. The centralized clock distribution system dissipates significant power due to the switching capacitance of the network.

Typically, the power dissipated in the clock distribution system comprises approximately 25% of the overall machine power. The power dissipated is directly proportional to the frequency of the clock signal and is described by the following equation:

P_{clock}=C·V²·F

where:
P_{clock}=Clock Distribution Power
C=Switched Capacitance
V=Supply Voltage
F=Clock Frequency

As the clock frequency increases in response to a higher demand for speed and data-throughput, the power dissipated in the clock distribution system also increases.

The register power can be approximated to be about 50% of the overall machine power on a typical machine. (For a deeply pipelined machined, the register power may comprise upwards of 70% of the overall machine power.) Thus, the clock distribution system and the pipeline registers together constitute over 75% of the overall machine power.

As micro architectures have become more complex and utilize deeper pipelines, it has become more difficult to thoroughly test the combinational logic in each pipeline stage. One way to ease the burden of testing different pipeline stages is to use pipeline registers and flip-flops that have a scan feature. The scan feature allows a set of test vectors to be inserted into a pipeline register in the middle of the pipeline and allows the result vectors to be scanned out of a pipeline register without having to wait for data to propagate through the entire pipeline. A major disadvantage of scannable registers and flip-flops is that they consume more chip area than a non-scannable flip-flop. Thus, the power consumed by the pipeline registers increases.

Therefore, there is a need for a scannable digital storage element that reduces power dissipation in the clock distribution system and in the pipeline registers while maintaining a high data-throughput rate.

### SUMMARY OF THE INVENTION

The foregoing discussed drawbacks and deficiencies of the prior art are overcome or alleviated by a design structure embodied in a machine readable medium used in a design process, the design structure including a circuit for data storage. The circuit includes a double edge clock generation circuit for generating a pulse clock signal having first and second clock pulses for each clock cycle of a system clock. The circuit also includes a scan clock generation circuit for generating first and second scan clock signals. The circuit further includes a scannable pulse flip-flop circuit having a data input and a data output that are connected with an internal storage node. The scannable pulse flip-flop circuit further has a scan input and a scan output that are connected with the internal storage node. The scannable pulse flip-flop circuit is receptive to the pulse clock signal and the scan clock signals. The scannable pulse flip-flop circuit is configured to be operable in a function mode of operation and a scan mode of operation. In the function mode of operation, the first and second scan clock signals are held at a logic level to allow data to pass from the data input to the internal storage node at the first clock pulse and from the internal storage node to the data output at the second clock pulse signal. In the scan mode of operation the pulse clock signal is held at a logic level to allow data to pass from the scan input to the internal storage node at a pulse of the first scan clock signal and from the internal storage node to the scan output at a pulse of the second scan clock signal.

### BRIEF DESCRIPTION OF THE DRAWINGS

The subject matter, which is regarded as the invention, is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates schematically one example of a double edge clock generation circuit that includes scan control;

FIG. 2 illustrates one example of a timing diagram for the double edge clock generation circuit of FIG. 1;

FIG. 3 illustrates schematically one example of a scannable pulsed flip-flop circuit;

FIG. 4 illustrates schematically one example of a scan clock generation circuit;

FIG. 5 illustrates one example of a timing diagram for the scan clock generation circuit of FIG. 4;

FIG. 6 illustrates one example of multiple registers showing scan functionality;

FIG. 7 illustrates one example of a timing diagram for the system of FIG. 6; and

FIG. 8 is a flow diagram of an exemplary design process used in semiconductor design, manufacturing, and/or test.

### DETAILED DESCRIPTION OF THE INVENTION

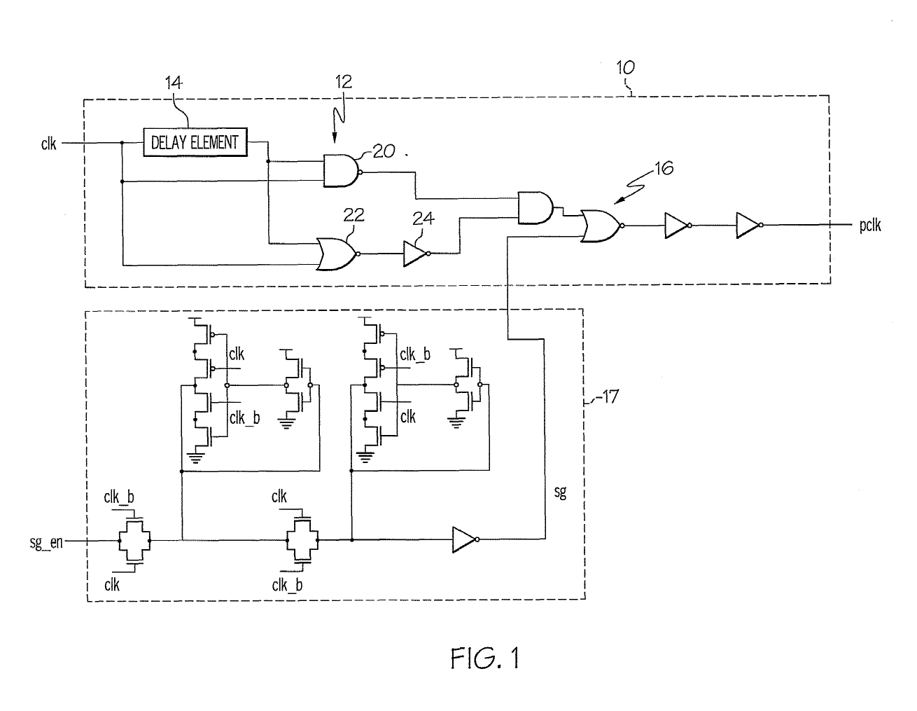

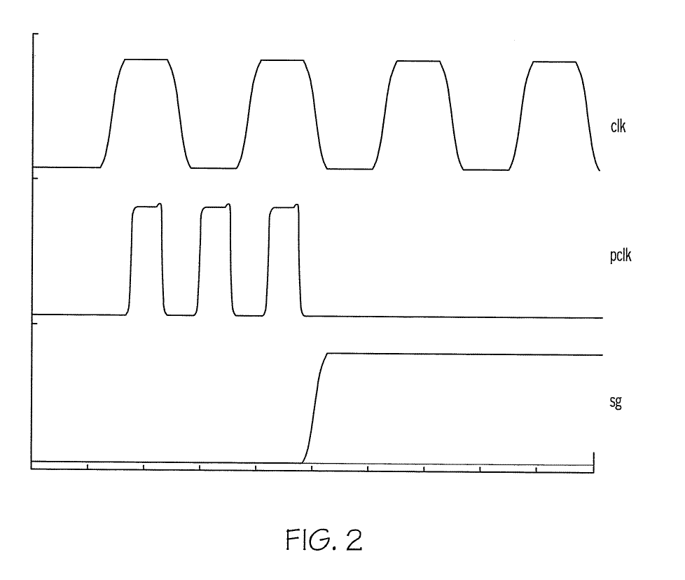

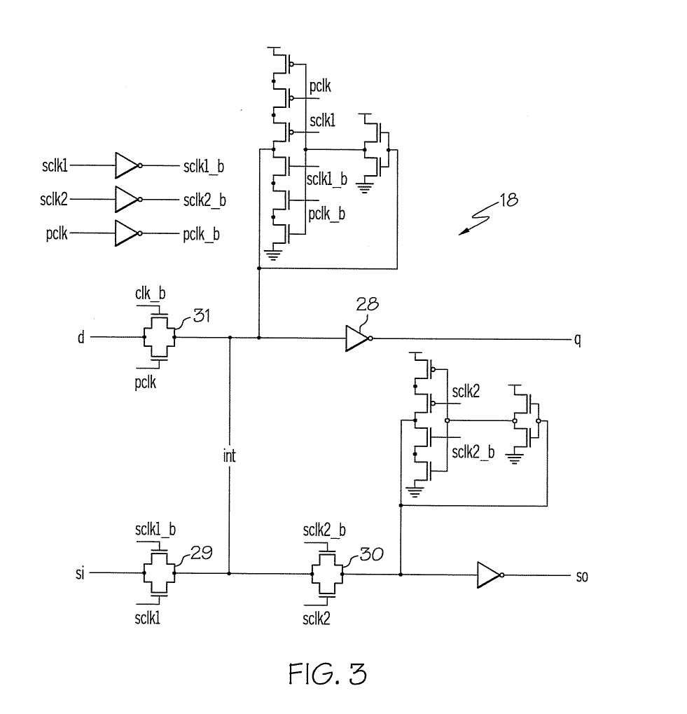

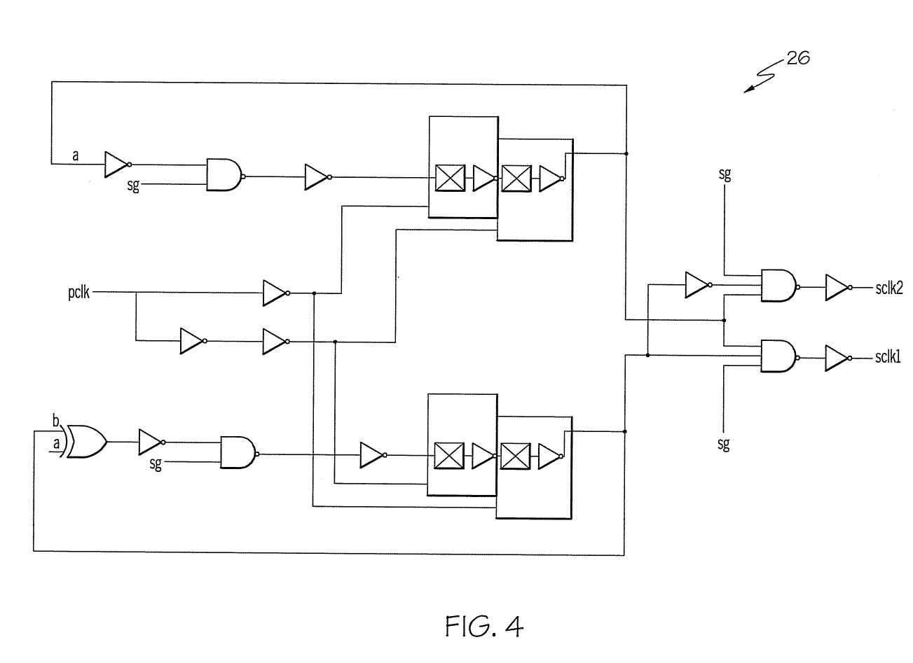

Turning now to the drawings in greater detail, it will be seen that in FIG. 1 there is a double edge clock generation circuit 10 and in FIG. 2 there is timing diagram for the double edge clock generation circuit 10. The double edge clock generation circuit 10 produces two clock signals per each system clock cycle, and includes additional control circuitry to control scan operations. A scannable pulsed flip-flop circuit 18 (not shown in FIG. 1, but is described in more detail hereinafter with reference to FIG. 3) is used in conjunction with the double edge clock generation circuit 10, thereby permitting reading/writing of functional data for test and debug. A scan clock generation circuit 26 (not shown in FIG. 1, but is described in more detail hereinafter with reference to FIG. 4) provides underlapped scan clocks and operates in conjunction with the above to provide safe clock generation.

The double edge clock generation circuit 10 includes a clock pulse generation circuit 12 with an inverting clock delay circuit 14 for generating positive and negative edge triggered pulses, and a scan function controlling AOI (AND-OR-Invert) circuit 16. A negative edge-triggered flip-flop 17 accepts scan gating control, wherein an input (scan gate enabled “sg_n”) generates an output (scan gate “sg”). The clock pulse generation circuit 12 creates clock control signals on both edges of a master clock as shown in FIG. 2 in two separate modes.

In a functional mode the scan-gate (“sg”) is held low (i.e., scan de-asserted). When the scan-gate control is held low (i.e., de-asserted), the inverting clock delay circuit 14 keeps the logical inverse of the previous state of the master clock (“clk”) for a predetermined amount of time. When the clock transitions, the delayed clock is compared to the new state in a NAND gate 20 and a NOR gate 22. If “clk” rises, the delayed clock remains high for the short (delayed) period of time; the output of the NAND gate 20 then pulses low until the delayed clock rises. This signal ultimately generates the rising edge (of “clk”) triggered pulse (for “pclk”) in the timing diagram of FIG. 2. If “clk” falls, the delayed clock remains low for the short (delayed) period of time; the output of the NOR gate 22 then pulses high until the delayed clock rises. The output the NOR gate 22 is inverted by an inverter 24 to match the rising edge pulse. This signal ultimately generates the falling edge (of “clk”) triggered pulse (for “pclk”) in the timing diagram of FIG. 2. The pulses from the rising edge (i.e., from the NAND gate 20) and falling edge (i.e., from the NOR gate 22) are combined along with the local scan-gate signal “sg”, which is assumed low during this time, to generate the clock signal “pclk” in the timing diagram of FIG. 2. Note that “pclk” pulses twice per cycle, once per “clk” edge. The “pclk” signal is then sent to the scannable pulsed flip-flop circuit 18, described hereinafter with reference to FIG. 3.

In a scan mode, the scan-gate (“sg”) is high (i.e., scan asserted), whereby set-up and hold is relative to system clock negative edge. When in scan operation mode, the “sg” signal disables the standard “pclk” operation. The “sg” signal rising edge is set-up to the falling edge of “clk”. This allows the disabling of the “pclk” pulses. The “pclk” signal is then forced low via the AOI circuit 16 in the clock control path and cannot trigger. When the scan operation is complete, the “sg” signal falling edge is set-up to the falling edge of “clk” to enable the “pclk” pulses. The scan operation (“sg”) is discussed in more detail hereinafter. The clock signal “pclk” is routed to a register comprised of the scannable pulsed flip-flop circuit 18, a single bit of which is shown in FIG. 3.

Turning now to FIG. 3, the scannable pulsed flip-flop circuit 18 operates within the two modes of operation described with respect to the double edge clock generation circuit 10, i.e., the function mode and the scan mode. During the functional mode, scan clocks “sclk1” and “sclk2” are continually held low, driven by scan clock generation circuit 26, described hereinafter with reference to FIG. 4. When the “pclk” pulses high (from the double edge clock generation circuit 10, pulsing twice per cycle as see in FIG. 2), the data is allowed to pass from a data input node “d” through a latch 31 to an internal storage node “int”. The stored data is then transferred (and inverted) to a data output node “q” through an inverter 28. When the “pclk” pulse ends, the data is stored on the internal node until the next “pclk” pulse arrives. In this way, any logic connected to the output of the flip-flop is permitted to evaluate based on the stored data.

In the scan mode, the signal “sclk2” connects the stored data at the internal storage node to a slave scan latch 30 and, subsequently, to a scan output node “so” which is the scan output of the pulsed flip-flop 18. Signal “sclk1” connects a scan input node “si” to a master scan latch 29 and, subsequently, to the internal storage node “int”. The scan clock generation circuit 26 (FIG. 4) drives the scan clocks. The scan clocks are pulsed alternative high in an underlapped fashion in order to read and write the stored data at the internal storage node “int”, which, then, affects the output state of the flip-flop bit. It will be noted that during this time that the “pclk” system is held low as shown in FIG. 2.

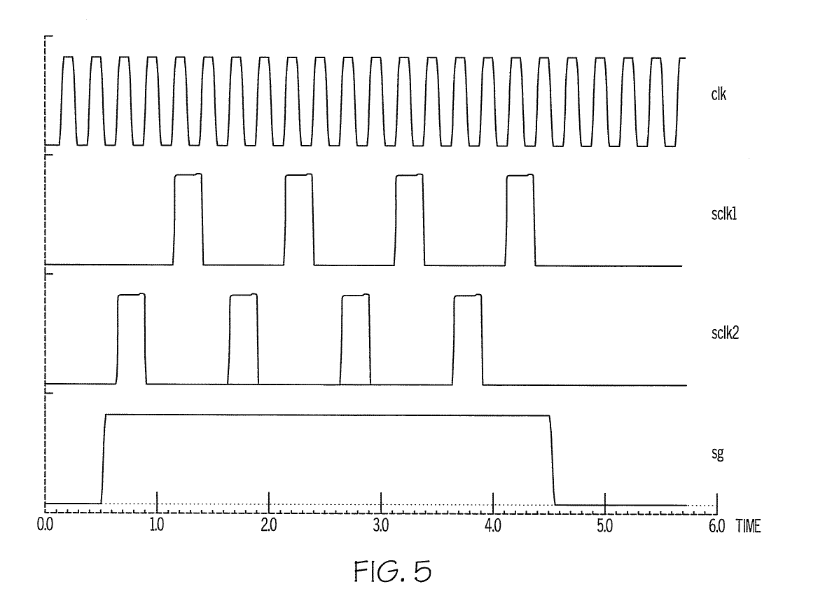

Turning now to FIG. 4, the scan clocks, “sclk1” and “sclk2”, are driven from the scan clock generation circuit 26, with FIG. 5 showing a timing diagram/simulation for the scan clock generation circuit 26. The scan clock generation circuit 26 is a 2-bit state circuit for generating underlapped clocks to drive the scannable pulsed flip-flop circuit 18. When “sg” transitions high, enabling scan operations, the scan clock generation circuit 26 begins is the “00” state and both “sclk2” and “sclk1” are held low. At the next master clock (“clk”) transition, the scan clock generation circuit 26 transitions to “01” and the signal “sclk2” is driven high. The “sclk1” remains low. At the next “clk” transition, the scan clock generation circuit 26 transitions to “11” and “sclk2” falls. The “sclk1” remains low. At the next “clk” transition, the scan clock generation circuit 26 transitions to “10” and “sclk1” rises. The “sclk2” remains low. At the next “clk” transition, the scan clock generation circuit 26 transitions to “00” and “sclk1” falls. The “sclk2” remains low. The scan clock generation circuit 26 continues to count, producing the signals as shown in the timing diagram/simulation of FIG. 5 until “sg” returns low, at which time the scan function is considered over and the functional clocking restarts. It will be noted that this operation occurs when the “pclk” pulses of the double edge clock generation circuit 10 (FIG. 1) remain low as is seen in the timing diagram of FIG. 2. This prevents contention in the scannable pulsed flip-flop circuit 18 (FIG. 3).

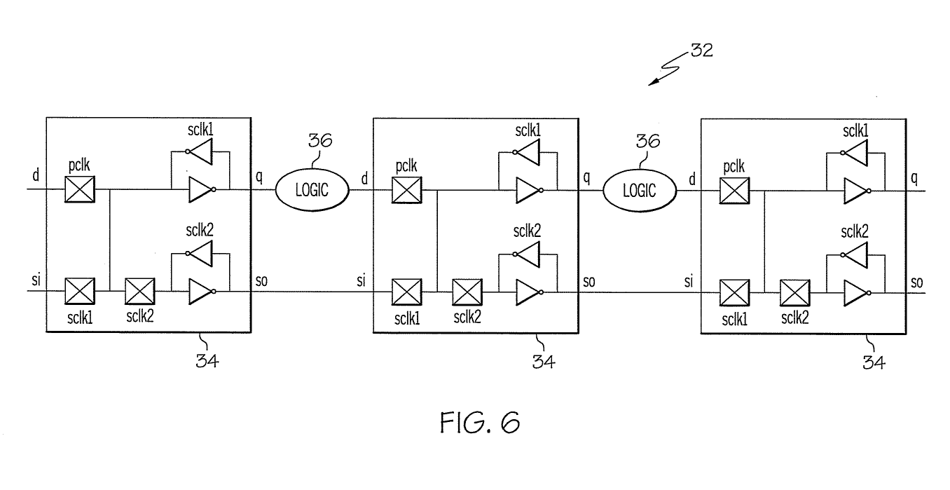

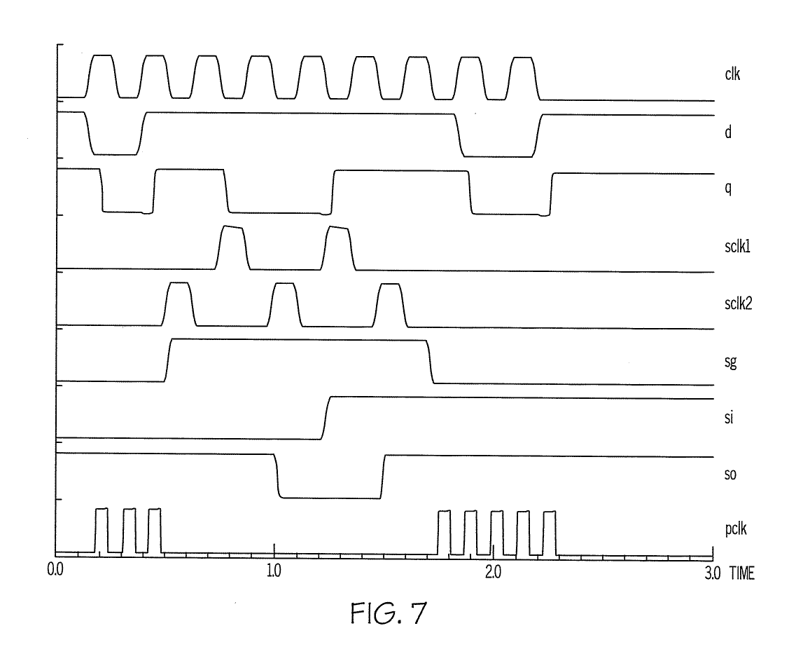

Turning now to FIG. 6, a double edge triggered pulse flip-flop system 32 is shown, with FIG. 7 showing a timing diagram for the double edge triggered pulse flip-flop system 32. In this exemplary embodiment, only a very simple system of single bit registers is shown. The overall concept can be expanded to any number of bits in the registers, rows of registers, etc. In the system of FIG. 6, note that the scan output of each register row 34 is connected to the scan input of the next register row 34. The “pclk” signals are each driven from a double edge clock generation circuit 10 (FIG. 1). The scan clocks, “sclk1” and “sclk2”, are each driven from a scan clock generation circuit 26 (FIG. 4).

In the functional mode operation, the data is launched twice every master clock (“nclk”) cycle by virtue of the “pclk” pulsing twice per cycle. Logic 36 between subsequent logical rows 34 of flops evaluates as the data is pumped through the system 32. At any time, the operation may be halted by a scan operation, described below, and the resulting evaluated data read and/or new preset data applied to the overall system for testing.

In the scan mode operation, when scan gate (“sg”) is driven low (set-up to fall of “clk”, as seen in FIG. 2), the “pclk” pulses are driven low (also seen in FIG. 2), disabling the data port of the scannable pulsed flip-flop circuit 18 (FIG. 3). It is important to note that during scan mode operation, the “pclk” signal remains low (as seen in FIG. 2), removing the data port (“d”) from affecting the internal storage node (“int”). This signifies the beginning of the scan operation and the scan clock generation circuit 26 (FIG. 4) assumes control of the flop clocking. The scan clock “sclk2” is pulsed high. This permits the data stored on all internal flop nodes (“int”) to be transferred to the slave scan latch 30, then placed on the scan output (“so”) of the scannable pulsed flip-flop circuit 18. Scan clock “sclk1” is pulsed high, transferring the previous functional data to the next master pulsed latch internal node (“int”). The “sclk2” pulses high, transferring the new master data into the next scan slave. Operation continues back-and-forth between “sclk2” and “sclk1” until the functional data appears sequentially on the system scan output. When the scan function is complete, the “sg” is de-asserted and the “pclk” pulse operation begins again.

An important feature of the scan mode operation is that scan begins with the “sclk2” assertions to preserve the stored evaluation data. For example, if the operation began with “sclk1”, then the functional data would be destroyed by the incoming scan-in data, losing the machine state to be read.

During the scan read function, an equivalent scan write may also be performed. Each register master node (“int”) is set to the desired state. The output of each register bit immediately receives the scan information through inverter 28. The logic connected to the output of the register 34 evaluates the new data, ultimately driving it the input of the next register's data (“d”) input. The evaluated data is not transferred to the register's master storage node “int” since “pclk” remains low. At some point, “sg” is de-asserted and the “pclk” operation resumes. The functional operation with “pclk” immediately loads the functional data (which was awaiting on the normal data port), piping to the register bit output. This operation does not test the speed of the cycle's logic as the input was awaiting the “pclk” pulse. The next “pclk” pulse stores the data of the next cycle operation in a similar fashion. However, this data is forced through the logical pipe and is sampled at speed, allowing the cycle's operation to be testing for frequency. Each previous cycle, then, that received awaiting data also received new “at speed” data, allowing frequency testing to be similarly performed. At some point, “sg” is asserted again and the scan data can be read using the aforementioned method.

The scan mode operation is somewhat different than traditional scan functions, in that, the data output of the flip-flops is immediately evaluated rather than waiting on a slave/launch clock. However, it is important to note that debug and testability is preserved.

A sample register consisting of 32 bits was simulated for power consumption using the IBM “CPAM” power estimation tool. This was compared to a standard 32-bit STI-style master-slave flip-flop system of equivalent drive strength. The system clocks were adjusted for the two registers: the present system was clocked at 2 GHZ due to the double-pulse nature; the standard design was clocked at 4 GHZ to provide an equivalent data rate. Output loads were removed to preclude damping of the power data due to the load. The scan operation was disabled in both cases. Assuming a 20% data activity factor, the resulting power of the registers was shown to be: Pulsed Invention: 0.401 mW for 32-bit register; and Standard Master-Slave: 1.002 mW for 32-bit register. This represents a savings of approximately 60%. This value was rounded down to 50% for comparison purposes because of wire modeling. Additionally, the clock power is approximately 25% of the overall machine power and is directly proportional to frequency from the equation P=C*V²*F and consumes approximately 25% of the overall system power. Since the clock in the new system runs at one-half the frequency of a traditional system, an additional power savings of (50%)*(25%), or 12.5%. Therefore, the estimated power savings of the system is the sum of the register and the clock savings, or ˜37.5%.

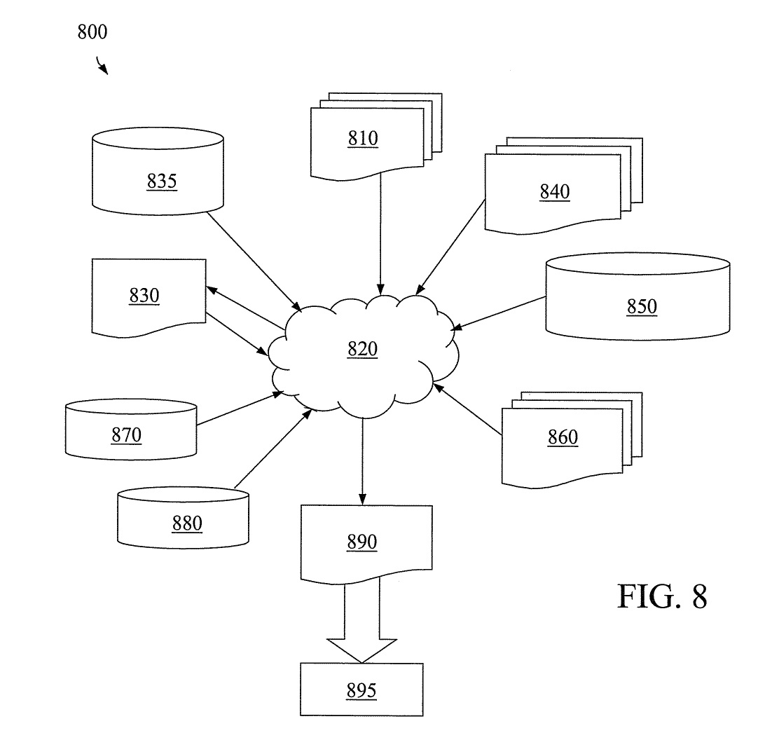

FIG. 8 is a block diagram illustrating an example of a design flow 800. Design flow 800 may vary depending on the type of IC being designed. For example, a design flow 800 for building an application specific IC (ASIC) will differ from a design flow 800 for designing a standard component. Design structure 810 is preferably an input to a design process 820 and may come from an IP provider, a core developer, or other design company or may be generated by the operator of the design flow, or from other sources. Design structure 810 comprises circuit embodiments 10, 18, 26, 32 in the form of schematics or HDL, a hardware-description language, (e.g., Verilog, VHDL, C, etc.). Design structure 810 may be contained on one or more machine readable medium(s). For example, design structure 810 may be a text file or a graphical representation of circuit embodiments 10, 18, 26, 32 illustrated in FIGS. 1, 3, 4 and 6. Design process 820 synthesizes (or translates) circuit embodiments 100, 200 into a netlist 830, where netlist 830 is, for example, a list of wires, transistors, logic gates, control circuits, I/O, models, etc., and describes the connections to other elements and circuits in an integrated circuit design and recorded on at least one of a machine readable medium. This may be an iterative process in which netlist 830 is resynthesized one or more times depending on design specifications and parameters for the circuit.

Design process 820 includes using a variety of inputs; for example, inputs from library elements 835 which may house a set of commonly used elements, circuits, and devices, including models, layouts, and symbolic representations, for a given manufacturing technology (e.g., different technology nodes, 32 nm, 45 nm, 90 nm, etc.), design specifications 840, characterization data 850, verification data 860, design rules 870, and test data files 880, which may include test patterns and other testing information. Design process 820 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 820 without deviating from the scope and spirit of the invention. The design structure of the invention embodiments is not limited to any specific design flow.

Design process 820 preferably translates embodiments of the invention as shown in FIGS. 1, 3, 4 and 6, along with any additional integrated circuit design or data (if applicable), into a second design structure 890. Second design structure 890 resides on a storage medium in a data format used for the exchange of layout data of integrated circuits (e.g., information stored in a GDSII (GDS2), GL1, OASIS, or any other suitable format for storing such design structures). Second design structure 890 may comprise information such as, for example, test data files, design content files, manufacturing data, layout parameters, wires, levels of metal, vias, shapes, data for routing through the manufacturing line, and any other data required by a semiconductor manufacturer to produce embodiments of the invention as shown in FIGS. 1, 3, 4 and 6. Second design structure 890 may then proceed to a stage 895 where, for example, second design structure 890: proceeds to tape-out, is released to manufacturing, is released to a mask house, is sent to another design house, is sent back to the customer, etc.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

There may be many variations to the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A design structure embodied in a machine readable medium used in a design process, the design structure comprising:
a circuit for data storage, including a double edge clock generation circuit for generating a pulse clock signal having first and second clock pulses for each clock cycle of a system clock;
a scan clock generation circuit for generating first and second scan clock signals; and
a scannable pulse flip-flop circuit having a data input and a data output that are connected with an internal storage node, the scannable pulse flip-flop circuit further having a scan input and a scan output that are connected with the internal storage node, the scannable pulse flip-flop circuit receptive to the pulse clock signal and the scan clock signals, the scannable pulse flip-flop circuit is configured to be operable in a function mode of operation and a scan mode of operation, in the function mode of operation the first and second scan clock signals are held at a logic level to allow data to pass from the data input to the internal storage node at the first clock pulse and from the internal storage node to the data output at the second clock pulse signal, in the scan mode of operation the pulse clock signal is held at a logic level to allow data to pass from the scan input to the internal storage node at a pulse of the first scan clock signal and from the internal storage node to the scan output at a pulse of the second scan clock signal.

2. The design structure of claim 1, wherein the scannable pulse flip-flop circuit further comprises an inverter at the data output for inverting the data at the data output.

3. The design structure of claim 1, wherein the scannable pulse flip-flop circuit further comprises an inverter at the scan output for inverting the data at the scan output.

4. The design structure of claim 1, wherein the double edge clock generation circuit comprises:
a clock pulse generation circuit for generating the first clock pulse at a rising edge of each clock cycle of a system clock and the second clock pulse at the falling edge of each clock cycle of a system clock; and
an AOI circuit is connected to the scan output of the scannable pulse flip-flop circuit, in the scan mode of operation the pulse clock signal is held at the logic level by the AOI circuit in response to data at the scan output.

5. The design structure of claim 4, wherein the double edge clock generation circuit further comprises:
an inverting clock delay circuit for introducing a delay to the system clock.

6. The design structure of claim 4, further comprising:
a negative edge-triggered flip-flop connected to the AOI circuit for holding the pulse clock signal at the logic level.

7. The design structure of claim 1, wherein the scan clock generation circuit further generates the first and second scan clock signals such that they are underlapping.

8. The design structure of claim 1, further comprising a plurality of the scannable pulse flip-flop circuits configured as registers, wherein one of the scannable pulse flip-flop circuits comprises one of the registers for storage of a single bit, the registers further configured in register rows, wherein the number of registers in a row corresponds to a number of bits in a word.

9. The design structure of claim 1, wherein the design structure comprises a netlist describing the circuit for data storage.

10. The design structure of claim 1, wherein the design structure resides on storage medium as a data format used for the exchange of layout data of integrated circuits.

11. The design structure of claim 1, wherein the design structure includes at least one of test data files, characterization data, verification data, programming data, or design specifications.
